(19) United States
(12) Patent Application Publication
(10) Pub. No.: US 2026/0047369 A1
(43) Pub. Date: Feb. 12, 2026

(54) UNIFORM SILICON OXIDE ETCHING METHODS

(71) Applicant: Applied Materials, Inc., Santa Clara, CA (US)

(72) Inventors: Shi Che, Sunnyvale, CA (US); Lala Zhu, Fremont, CA (US); Yimin Huang, Santa Clara, CA (US); Anchuan Wang, San Jose, CA (US); Nitin K. Ingle, San Jose, CA (US)

(73) Assignee: Applied Materials, Inc., Santa Clara, CA (US)

(21) Appl. No.: 18/796,747

(22) Filed: Aug. 7, 2024

(51) Int. Cl. H01L 21/311

(52) U.S. Cl. CPC H01L 21/31116

(57) ABSTRACT

Exemplary semiconductor processing methods may include providing a first fluorine-containing precursor and a nitrogen-containing precursor to a processing region of a semiconductor processing chamber. A substrate may be disposed within the processing region. One or more features may extend through alternating layers of a silicon-and-oxygen-containing material and a silicon-and-nitrogen-containing material are disposed on the substrate. The methods may include providing a second fluorine-containing precursor to the processing region of the semiconductor processing chamber. The methods may include contacting the substrate with the first fluorine-containing precursor, the nitrogen-containing precursor, and the second fluorine-containing precursor. The contacting may etch a portion of the silicon-and-oxygen-containing material, and wherein a top-to-bottom loading is characterized by less than 1.2.

### TECHNICAL FIELD

The present technology relates to semiconductor processes and equipment. More specifically, the present technology relates to isotropically etching materials relative to other materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a first fluorine-containing precursor and a nitrogen-containing precursor to a processing region of a semiconductor processing chamber. A substrate may be disposed within the processing region. One or more features may extend through alternating layers of a silicon-and-oxygen-containing material and a silicon-and-nitrogen-containing material are disposed on the substrate. The methods may include providing a second fluorine-containing precursor to the processing region of the semiconductor processing chamber. The methods may include contacting the substrate with the first fluorine-containing precursor, the nitrogen-containing precursor, and the second fluorine-containing precursor. The contacting may etch a portion of the silicon-and-oxygen-containing material, and wherein a top-to-bottom loading is characterized by less than 1.2.

In some embodiments, the first fluorine-containing precursor may be or include hydrogen fluoride (HF). The nitrogen-containing precursor may be or include ammonia (NH₃). The silicon-and-nitrogen-containing material may further include oxygen and/or carbon. A flow rate ratio of the first fluorine-containing precursor relative to the nitrogen-containing precursor may be between about 0.5:1 and about 2:1. The second fluorine-containing precursor may be or include silicon tetrafluoride (SiF₄). A flow rate ratio of the second fluorine-containing precursor relative to the nitrogen-containing precursor may be greater than or about 0.5:1. The methods may include forming remote plasma effluents of the first fluorine-containing precursor and the nitrogen-containing precursor. The first fluorine-containing precursor, the nitrogen-containing precursor, and the second fluorine-containing precursor may form ammonium fluorosilicate ((NH₄)₂SiF₆). A top-to-bottom loading may be characterized by less than 1. An etch rate of the silicon-and-oxygen-containing material may be less than or about 20 Å/second. A temperature within the processing region may be maintained at less than or about 150° C. A pressure within the processing region may be maintained at less than or about 15 Torr.

Some embodiments of the present technology may encompass semiconductor processing methods. The methods may include providing a fluorine-containing precursor and a nitrogen-containing precursor to a processing region of a semiconductor processing chamber. A substrate may be disposed within the processing region. One or more features may extend through alternating layers of a silicon-and-oxygen-containing material and a silicon-and-nitrogen-containing material are disposed on the substrate. The methods may include providing a silicon-and-fluorine-containing precursor to the processing region of the semiconductor processing chamber. The fluorine-containing precursor, the nitrogen-containing precursor, and the silicon-and-fluorine-containing precursor may form ammonium fluorosilicate ((NH₄)₂SiF₆). The methods may include contacting the substrate with the fluorine-containing precursor, the nitrogen-containing precursor, and the silicon-and-fluorine-containing precursor. The contacting may etch a portion of the silicon-and-oxygen-containing material.

In some embodiments, the one or more features may be characterized by an aspect ratio of greater than or about 2:1. The processing region may be maintained plasma-free while contacting the substrate with the fluorine-containing precursor, the nitrogen-containing precursor, and the silicon-and-fluorine-containing precursor. A top-to-bottom loading may be characterized by less than 1.2.

Some embodiments of the present technology may encompass semiconductor processing methods. The methods may include providing a fluorine-containing precursor and a nitrogen-containing precursor to a processing region of a semiconductor processing chamber. A substrate may be disposed within the processing region. A layer of a silicon-and-oxygen-containing material disposed on the substrate may define one or more features. The methods may include providing a silicon-and-fluorine-containing precursor to the processing region of the semiconductor processing chamber. The fluorine-containing precursor, the nitrogen-containing precursor, and the silicon-and-fluorine-containing precursor may form ammonium fluorosilicate ((NH₄)₂SiF₆). The methods may include contacting the substrate with the fluorine-containing precursor, the nitrogen-containing precursor, and the silicon-and-fluorine-containing precursor. The contacting may etch a portion of the layer of the silicon-and-oxygen-containing material. A top-to-bottom loading may be characterized by less than 1.1.

In some embodiments, the one or more features may be characterized by a depth of greater than or about 50 nm. A flow rate of the silicon-and-fluorine-containing precursor may be less than a flow rate of the fluorine-containing precursor and a flow rate of the nitrogen-containing precursor.

Such technology may provide numerous benefits over conventional systems and techniques. For example, the processes may selectively etch silicon-and-oxygen-containing material isotropically within semiconductor structures. Additionally, the processes may uniformly etch silicon-and-oxygen-containing material to reduce top-to-bottom loading. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

FIG. 3 shows a bottom plan view of an exemplary showerhead according to some embodiments of the present technology.

FIG. 4 shows exemplary operations in a method according to some embodiments of the present technology.

FIGS. 5A-5B show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D NAND to 3D NAND, many process operations are modified from vertical to horizontal operations. Additionally, as 3D NAND structures grow in the number of cells being formed, the aspect ratios of features, such as memory holes and other structures, increase, sometimes dramatically. During 3D NAND processing, stacks of placeholder layers and dielectric materials may form the inter-electrode dielectric or IPD layers. These placeholder layers may have a variety of operations performed to place structures before fully removing the material and replacing it with metal. Additionally, the dielectric materials may be recessed depending on the structure or device. While the metallization may be incorporated on one side of the cell structure, operations may have previously been performed on the other side of the structure, such as forming floating gates or charge-trap layers. Although these layers may be formed within the memory hole, crosstalk between vertically separated memory cells may occur. One way to reduce this communication may include etching the placeholder material before forming these layers to allow dielectric material to further separate the individual cell material layers from adjacent cells.

Some conventional technologies utilize a wet etch to access each of the cell placeholder materials to perform a lateral etch of dielectric materials. However, wet etching may be more robust than other etching techniques, and the wet etching may etch materials further than necessary or desired with reduced selectivity. For example, the wet etching may over etch some features. Additionally, wet etching of small form factor structures may cause pattern collapse or deformation due to surface tension of the etchant. Using wet etchants may also create the need for subsequent operations to remove residues formed within the trenches or holes. Dry etching techniques may also be performed, however many of the dry etchants utilized additionally etch other materials, reducing selectivity of the process. Additionally, dry etchants may have difficulty diffusing an entire length or depth of the features, resulting in a non-uniform etch along the entire length or depth of the features.

The present technology overcomes these issues, as well as other issues associated with other applications, such as logic structures, by performing a dry etch process which may selectively etch silicon-and-oxygen-containing material oxide laterally, while limiting etching of silicon-and-nitrogen-containing material. By utilizing particular precursor combinations, exposed surfaces of the silicon-and-oxygen-containing material may be etched uniformly along the entire length or depth of the features. In this way, the present technology may address top-to-bottom loading issues associated with the diffusion issues of conventional dry etching technologies.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

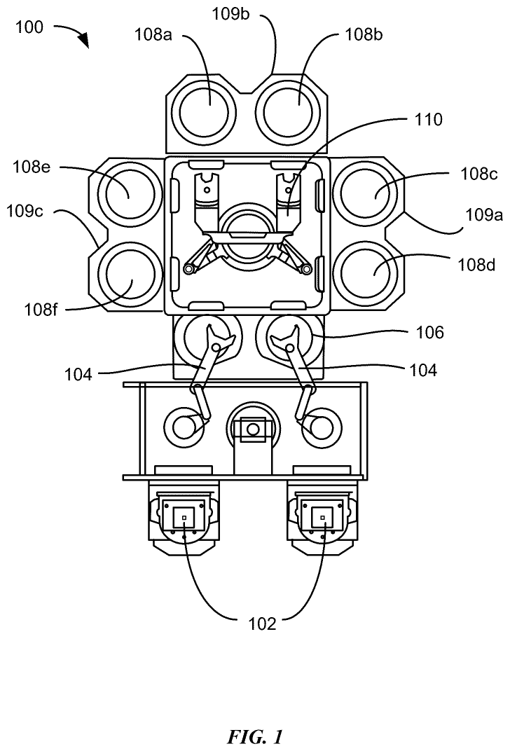

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

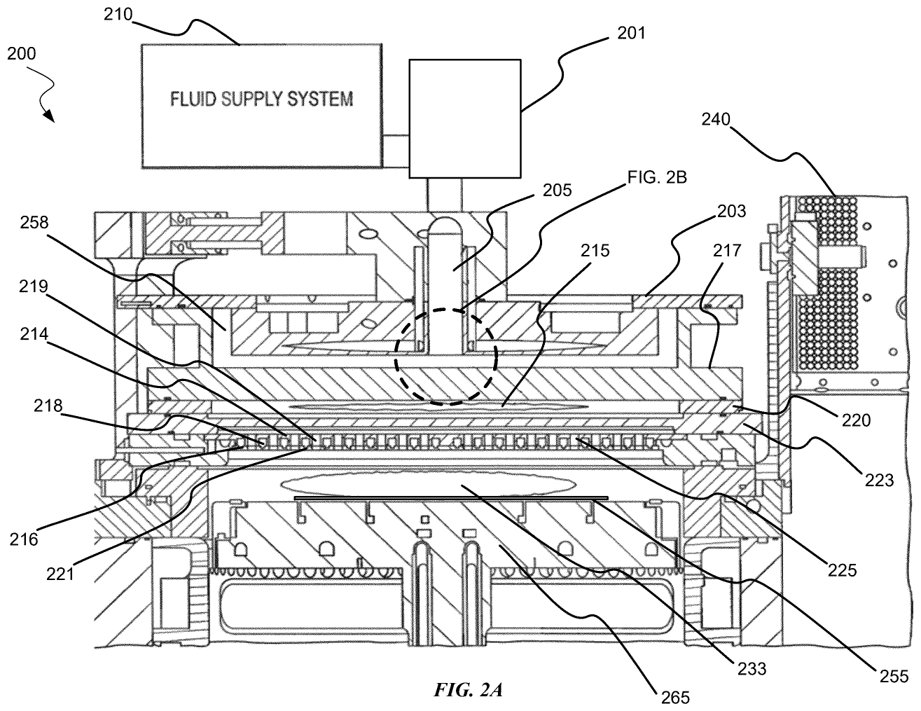

FIG. 2A shows a cross-sectional view of an exemplary process chamber system 200 with partitioned plasma generation regions within the processing chamber, and which may be configured to perform processes as described further below. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system 201 may optionally be included in the system, and may process a first gas which then travels through gas inlet assembly 205. The inlet assembly 205 may include two or more distinct gas supply channels where the second channel may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems, such as microwave plasma-generating systems.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter etch selectivity, e.g., SiNx:SiOx etch ratios, Si:SiOx etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

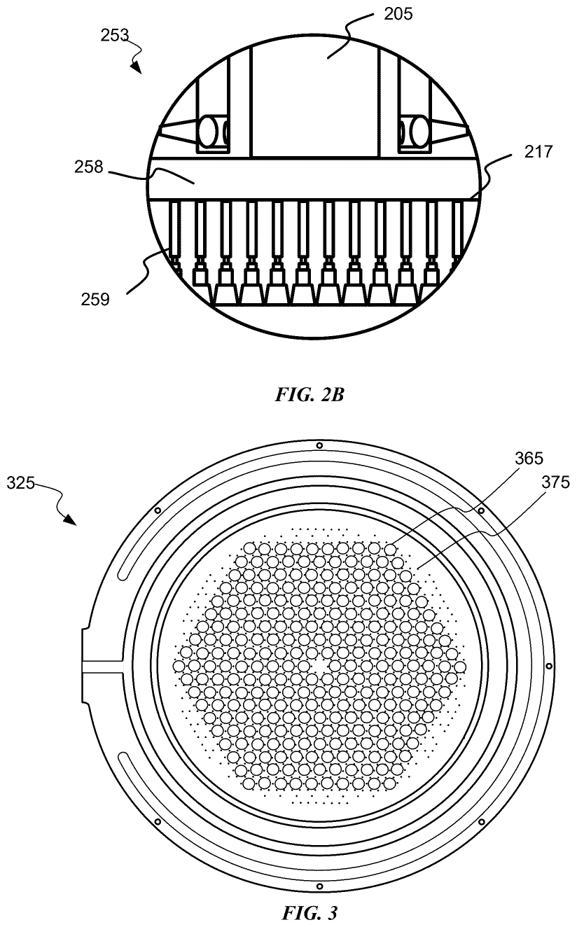

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

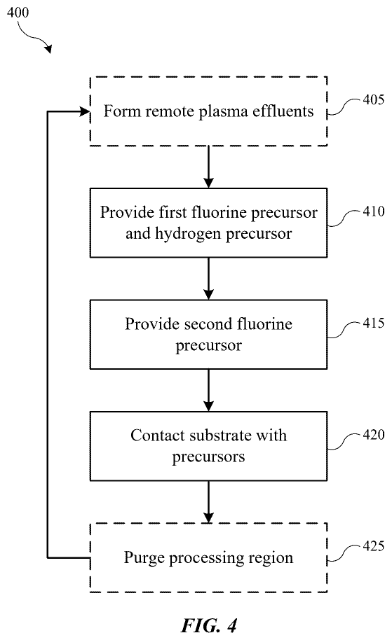

The chambers discussed previously may be used in performing exemplary methods including etching methods. Turning to FIG. 4 is shown exemplary operations in a method 400 according to embodiments of the present technology. Prior to the first operation of the method a substrate may be processed in one or more ways before being placed within a processing region of a chamber in which method 400 may be performed. For example, IPD layers may be formed on the substrate and then one or more features, such as memory holes or trenches, may be formed through the stacked layers. The IPD layers may include any number of materials, and may include alternating layers of a placeholder material and a dielectric material. In embodiments the dielectric material may be or include a silicon-and-oxygen-containing material (e.g., silicon oxide), and the placeholder material may be or include silicon-and-nitrogen-containing material (e.g., silicon nitride). In embodiments, the silicon-and-nitrogen-containing material may further include oxygen and/or carbon. Although the remaining disclosure will discuss silicon-and-oxygen-containing material and silicon-and-nitrogen-containing material, any other known materials used in these two layers may be substituted for one or more of the layers. Some or all of these operations may be performed in chambers or system tools as previously described, or may be performed in different chambers on the same system tool, which may include the chamber in which the operations of method 400 are performed.

Method 400 may include providing a gaseous mixture including multiple fluorine-containing precursors to a processing region of a semiconductor processing chamber to selectively and uniformly etch silicon-and-oxygen-containing material. An exemplary chamber may be chamber 200 previously described, which may include one or both of the RPS unit 201 or first plasma region 215. In embodiments, method 400 may include forming remote plasma effluents of one or more of the precursors at optional operation 405. Either or both of RPS unit 201 or first plasma region 215 may be the remote plasma region used in operation 405. At operation 410, method 400 may include providing a first fluorine-containing precursor and a nitrogen-containing precursor or, if formed, remote plasma effluents of either precursor to the processing region. At operation 415, method 400 may include providing a second fluorine-containing precursor or, if formed, remote plasma effluents of the second fluorine-containing precursor to the processing region. At operation 420, method 400 may include contacting the substrate with the precursors. The contacting may etch a portion of the dielectric material, such as the silicon-and-oxygen-containing material. At optional operation 425, method 400 may include purging the processing region. The purge may remove residual precursor material or plasma effluents thereof as well as etch byproducts.

As noted, the substrate may include a silicon or silicon-containing substrate or wafer on which a number of layers of material have been formed, such as alternating layers of silicon-and-oxygen-containing material and silicon-and-nitrogen-containing material. A feature, such as a memory hole or a trench, may be formed through the stacked layers that extends to the level of the substrate, which may provide an exposed portion of the substrate at the bottom of the hole or trench. In this way, within the feature structure, there may be exposed regions of silicon-and-oxygen-containing material, silicon-and-nitrogen-containing material, and silicon or some other silicon-containing material. The formation of the feature may have occurred in a different chamber, or at some previous operation. If performed within the same chamber as method 400, the exposed portion of the surface of the substrate may be relatively clean or neat. However, if the process was performed in a different chamber, or in a different environment, there may be a native oxide formed over the exposed portion of the substrate through the feature. The native oxide may be different from the oxide formed in the alternating layers of the memory structure. For example, while the layers of silicon-and-oxygen-containing material that may be used to divide memory cells may be a relatively higher quality oxide, native oxide may be a relatively low-quality oxide, and may be relatively porous compared to the layers of silicon-and-oxygen-containing material.

The features may be characterized by an aspect ratio, or a ratio of height-to-width, of greater than or about 1:1, and may be characterized by an aspect ratio greater than or about 2:1, greater than or about 3:1, greater than or about 4:1, greater than or about 5:1, greater than or about 6:1, greater than or about 7:1, greater than or about 8:1, greater than or about 9:1, greater than or about 10:1, greater than or about 20:1, greater than or about 30:1, greater than or about 40:1, greater than or about 50:1, or more. Additionally, the features may be characterized by a depth of greater than or about 25 nm, and may be characterized by a depth of greater than or about 30 nm, greater than or about 40 nm, greater than or about 50 nm, greater than or 60 nm, greater than or about 70 nm, greater than or about 80 nm, greater than or 90 nm, greater than or about 100 nm, greater than or 250 nm, greater than or 500 nm, or more. Further, the features may be characterized by a critical dimension, or distance between sidewalls defining the features, such as a radius, of less than or about 100 nm, and may be characterized by a critical dimension of less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, or less.

Conventional ammonium fluoride (NH₄F) etch processes may struggle with top-to-bottom loading issues. Typically, NH₄F etch processes utilize hydrogen fluoride (HF) and ammonia (NH₃) to form NH₄F and ammonium bifluoride ((NH₄)F·HF) which may selectively etch silicon-and-oxygen-containing material. However, the HF/NH₃ or resultant NH₄F and (NH₄)F·HF may struggle to diffuse an entire length or depth of the features. As such, silicon-and-oxygen-containing material at upper portions of the features, near the opening of the features, may be etched more compared to silicon-and-oxygen-containing material at lower portions of the features, near the substrate. The present technology addresses these issues by introducing a second fluorine-containing precursor to reduce the etch rate of silicon-and-oxygen-containing material at upper portions of the features. This reduction in the etch rate of silicon-and-oxygen-containing material at upper portions of the features allows a more uniform etch of silicon-and-oxygen-containing material along the length or depth of the features.

While NH₄F etch processes may commonly utilize HF and NH₃ to selectively etch silicon-and-oxygen-containing material, the present technology may encompass other precursors. For example, the first fluorine-containing precursor may be any fluorine-containing precursor able to etch silicon-and-oxygen-containing material. In addition to HF, the first fluorine-containing precursor may be or include atomic fluorine (F), diatomic fluorine (F₂), nitrogen trifluoride (NF₃), carbon tetrafluoride (CF₄), xenon difluoride (XeF₂), as well as various other fluorine-containing precursors used or useful in semiconductor processing. Similarly, in addition to NH₃, the nitrogen-containing precursor may be or include atomic nitrogen (N), diatomic nitrogen (N₂), NF₃, dimide (N₂H₂), hydrazine (N₂H₄), as well as various other nitrogen-containing precursors used or useful in semiconductor processing. In embodiments, both a nitrogen-containing precursor and a hydrogen-containing precursor may be provided at operation 410. Exemplary hydrogen-containing precursors may be or include atomic hydrogen (H), diatomic hydrogen (H₂), HF, N₂H₂, N₂H₄, as well as various other hydrogen-containing precursors used or useful in semiconductor processing.

The second fluorine-containing precursor, serving to reduce the etch rate of silicon-and-oxygen-containing material at upper portions of the features, may further include silicon. For example, the second fluorine-containing precursor may be or include silicon tetrafluoride (SiF₄), hexafluorodisilane (Si₂F₆), as well as various other fluorine-containing precursors used or useful in semiconductor processing. Additionally, it is contemplated that multiple precursors may be provided to introduce silicon and/or fluorine to reduce the etch rate of silicon-and-oxygen-containing material at upper portions of the features. Carrier gases or inert gases may also be provided with the first fluorine-containing precursor, the nitrogen-containing precursor and/or hydrogen-containing precursor, and the second fluorine-containing precursor.

A flow rate of the first fluorine-containing precursor and the nitrogen-containing precursor may be approximately the same. However, it is also contemplated that flow rates of the first fluorine-containing precursor and the nitrogen-containing precursor may be different. In embodiments, a flow rate of the first fluorine-containing precursor and/or the nitrogen-containing precursor may be less than or about 1,000 sccm, and may be less than or about 750 sccm, less than or about 700 sccm, less than or about 650 sccm, less than or about 600 sccm, less than or about 575 sccm, less than or about 550 sccm, less than or about 525 sccm, less than or about 500 sccm, less than or about 490 sccm, less than or about 480 sccm, or less. At increased flow rates, the etch rate of the silicon-and-oxygen-containing material may increase. Conversely, at lower flow rates, the etch rate of the silicon-and-oxygen-containing material may decrease. In embodiments, the flow rate of the first fluorine-containing precursor and/or the nitrogen-containing precursor may be greater than or about 250 sccm, and may be greater than or about 300 sccm, greater than or about 350 sccm, greater than or about 400 sccm, greater than or about 425 sccm, greater than or about 450 sccm, greater than or about 460 sccm, greater than or about 470 sccm, greater than or about 480 sccm, or more. Accordingly, to maintain an efficient etch and also maintain control of the etch rate, the flow rate of the first fluorine-containing precursor and/or the nitrogen-containing precursor may be maintained between any of the values previously discussed.

In embodiments, a flow rate ratio of the first fluorine-containing precursor relative to the nitrogen-containing precursor may be between about 0.5:1 and about 2:1, and may be between about 0.55:1 and about 1.9:1, between about 0.6:1 and about 1.8:1, between about 0.65:1 and about 1.7:1, between about 0.7:1 and about 1.6:1, between about 0.75:1 and about 1.5:1, between about 0.8:1 and about 1.4:1, between about 0.85:1 and about 1.3:1, between about 0.9:1 and about 1.2:1, between about 0.95:1 and about 1.1:1, or about 1:1.

In embodiments, a flow rate of the second fluorine-containing precursor may be less than the flow rate of the fluorine-containing precursor and/or the flow rate of the nitrogen-containing precursor. The flow rate of the second fluorine-containing precursor may be greater than or about 100 sccm, and may be greater than or about 150 sccm, greater than or about 175 sccm, greater than or about 200 sccm, greater than or about 210 sccm, greater than or about 220 sccm, greater than or about 230 sccm, greater than or about 240 sccm, greater than or about 250 sccm, or more. As the flow rate of the second fluorine-containing precursor increases, the etch rate of silicon-and-oxygen-containing material at upper portions of the features may reduce. However, too much of the second fluorine-containing precursor may halt the etch entirely. As such, the flow rate of the second fluorine-containing precursor may be less than or about 500 sccm, and may be less than or about 450 sccm, less than or about 400 sccm, less than or about 350 sccm, less than or about 325 sccm, less than or about 300 sccm, less than or about 290 sccm, less than or about 280 sccm, less than or about 270 sccm, less than or about 260 sccm, less than or about 250 sccm, less than or about 240 sccm, or less.

A flow rate ratio of the second fluorine-containing precursor relative to the nitrogen-containing precursor may impact the etch rate of silicon-and-oxygen-containing materials. At higher flow rate ratios of the second fluorine-containing precursor relative to the nitrogen-containing precursor, the etch rate of the silicon-and-oxygen-containing material may reduce. In NH₄F etch processes, the increased presence of the second fluorine-containing precursor may produce additional byproduct, such as ammonium fluorosilicate ((NH₄)₂SiF₆), through reaction with the other precursors. This byproduct may reduce the rate at which the reaction to etch silicon-and-oxygen-containing material may proceed. As such, the flow rate ratio of the second fluorine-containing precursor relative to the nitrogen-containing precursor may be greater than or about 0.5:1, and may be greater than or about 0.6:1, greater than or about 0.7:1, greater than or about 0.8:1, greater than or about 0.9:1, greater than or about 1:1, greater than or about 1.3:1, greater than or about 1.2:1, greater than or about 1.3:1, greater than or about 1.4:1, greater than or about 1.5:1, greater than or about 1.6:1, greater than or about 1.8:1, greater than or about 2:1, or more. Again, too much of the second fluorine-containing precursor may halt the etch entirely. As such, the flow rate ratio of the second fluorine-containing precursor relative to the nitrogen-containing precursor may be less than or about 2.5:1, and may be less than or about 2:1, less than or about 1.5:1, less than or about 1:1, or less.

In embodiments, the flow rate of any of the precursors may be pulsed. For example, the flow rate of the second fluorine-containing precursor may be pulsed to reduce the effective amount of the second fluorine-containing precursor being provided to the processing region. As previously discussed, increased amounts of the second fluorine-containing precursor may reduce the etch rate of the silicon-and-oxygen-containing material. Therefore, pulsing the flow rate of the second fluorine-containing precursor may maintain a desired etch rate.

In embodiments, any one or more of the previously discussed precursors may be flowed directly to the processing region of the semiconductor processing chamber bypassing the remote plasma region. By bypassing the remote plasma region, plasma effluents of the precursors flowed directly to the processing region may not be formed. In such embodiments, the processing region may be maintained plasma-free and method 400 may be a thermal process. Conversely, some embodiments may include providing one or more of the previously discussed precursors to the remote plasma region. For example, method 400 may include forming remote plasma effluents of the first fluorine-containing precursor and the nitrogen-containing precursor. Plasma effluents of the one or more previously discussed precursors provided to the remote plasma region may be formed remotely from the processing region. The plasma effluents, if formed, may then be provided to the processing region. It is contemplated that plasma effluents of other precursors that bypass the remote plasma region may form due to contact with plasma effluents being generated in the remote plasma region and provided to the processing region. In cither embodiment, method 400 may not form plasma effluents locally in the processing region to prevent direct exposure of the substrate to plasma formation.

In conventional NH₄F etch processes using, for example, HF and NH₃, the HF and NH₃ may react with the silicon-and-oxygen-containing material to form (NH₄)₂SiF₆ and, depending on temperature, water or steam (H₂O). By including the second fluorine-containing precursor, such as SiF₄, the first fluorine-containing precursor, the nitrogen-containing precursor, and the second fluorine-containing precursor may form (NH₄)₂SiF₆. The formed (NH₄)₂SiF₆ may block HF and NH₃ from etching silicon-and-oxygen-containing material at upper portions of the features. Additionally, the second fluorine-containing precursor, such as SiF₄, may be characterized by a diffusion gradient along the depth or length of the features that results in more (NH₄)₂SiF₆ being formed at upper portions of the features. Thus, HF and NH₃ may diffuse toward lower portions of the features and more uniformly etch silicon-and-oxygen-containing material along the depth or length of the features.

As previously discussed, optional operation 425 may include purging the processing region. By performing an amount of etch followed by an amount of purge, a controlled lateral or isotropic etch of silicon-and-oxygen-containing material may be performed. To further facilitate etching, the present technology may be performed in a number of cycles to allow the removal of etch byproducts and facilitate delivery of etchants into the features. In some embodiments the operations, including the optional purge, may be performed in greater than or about 2 cycles, greater than or about 3 cycles, greater than or about 4 cycles, greater than or about 5 cycles, greater than or about 10 cycles, greater than or about 20 cycles, greater than or about 50 cycles, greater than or about 100 cycles, greater than or about 200 cycles, or more cycles, depending on factors such as the extent of silicon-and-oxygen-containing material etching to be performed, or other effects of the process.

In addition to increasing etch uniformity along a length or depth of the features, the present technology may control the etch rate to allow for a precise removal of silicon-and-oxygen-containing material. In embodiments, an etch rate of the silicon-and-oxygen-containing material may be less than or about 20 Å/second, and may be less than or about 19 Å/second, less than or about 18 Å/second, less than or about 17 Å/second, less than or about 16 Å/second, less than or about 15 Å/second, less than or about 14 Å/second, less than or about 13 Å/second, less than or about 12 Å/second, less than or about 11 Å/second, less than or about 10 Å/second, less than or about 8 Å/second, less than or about 6 Å/second, less than or about 4 Å/second, less than or about 2 Å/second, or less.

By performing the operations previously discussed, silicon-and-oxygen-containing material may be removed relative to silicon-and-nitrogen-containing material at a selectivity of greater than or about 2:1, and removed at a selectivity of greater than or about 3:1, greater than or about 4:1, greater than or about 5:1, greater than or about 10:1, greater than or about 15:1, greater than or about 20:1, greater than or about 25:1, greater than or about 30:1, or more.

Further, by performing the operations previously discussed, the top-to-bottom loading of the etching may be characterized by less than 1.2. The top-to-bottom loading may be measured by comparing an amount of etching at the uppermost silicon-and-oxygen-containing material relative to an amount of etching at the lowermost silicon-and-oxygen-containing material, or material closest to the substrate. In embodiments, the top-to-bottom loading of the etching may be characterized by less than 1.15, and may be characterized by less than or about 1.1, less than or about 1.05, less than or about 1, less than or about 0.95, less than or about 0.9, less than or about 0.85, less than or about 0.8, or less.

Process conditions may also impact the operations performed in method 400. Each of the operations of method 400 may be performed during a constant temperature in embodiments, while in some embodiments the temperature may be adjusted during different operations. Temperatures may be maintained in any range, however, at higher temperatures, the etch byproduct that slows the etch of silicon-and-oxygen-containing material at upper portions of the features may sublimate and may no longer impact top-to-bottom loading. Accordingly, in some embodiments the temperature may be maintained at less than or about 200° C., and may be maintained at less than or about 175° C., less than or about 150° C., less than or about 140° C., less than or about 130° C., less than or about 120° C., less than or about 110° C., less than or about 100° C., less than or about 90° C., less than or about 80° C., less than or about 70° C., less than or about 60° C., less than or about 50° C., less than or about 40° C., less than or about 30° C., or less.

In some embodiments, the process may occur at a variety of pressures, which may facilitate operations in any of a number of process chambers. For example, the process may be performed within chambers capable of providing pressures less than or about 15 Torr, such as less than or about 10 Torr, less than or about 9 Torr, less than or about 8 Torr, less than or about 7 Torr, less than or about 6 Torr, less than or about 5 Torr, less than or about 4.5 Torr, less than or about 4 Torr, less than or about 3.5 Torr, less than or about 3 Torr, less than or about 2.5 Torr, less than or about 2 Torr, less than or about 1.5 Torr, less than or about 1 Torr, or less. At increased pressures, the second fluorine-containing precursor, such as SiF₄, may remain at upper portions of the features, whereas reduced pressures may result in the second fluorine-containing precursor more easily diffusing into the features. Thus, at higher pressures, the second fluorine-containing precursor, such as SiF₄, may reduce the etch rate at upper portions of the features. Accordingly, the pressure may be maintained at greater than or about 1 Torr, and may be maintained at greater than or about 1.5 Torr, greater than or about 2 Torr, greater than or about 2.5 Tor, greater than or about 3 Torr, greater than or about 3.5 Torr, greater than or about 4 Torr, greater than or about 4.5 Torr, greater than or about 5 Torr, greater than or about 6 Torr, greater than or about 7 Torr, greater than or about 8 Torr, greater than or about 9 Torr, greater than or about 10 Torr, or more.

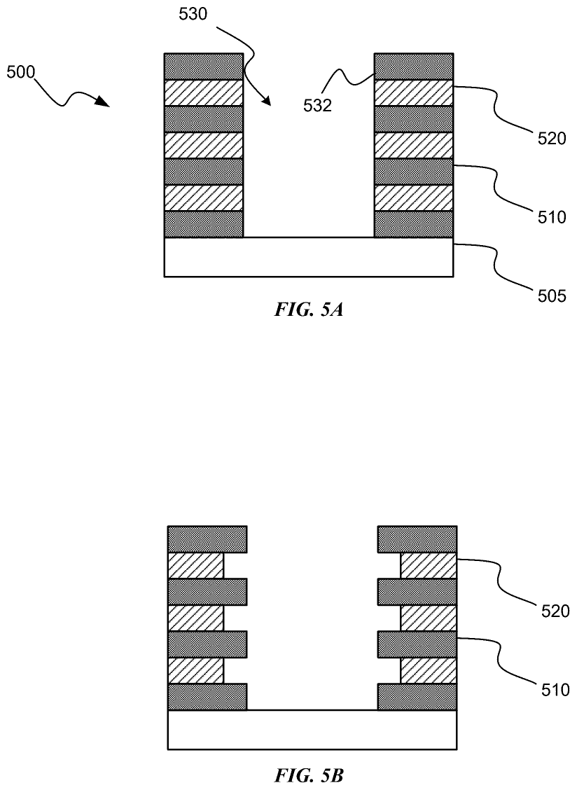

Turning to FIGS. 5A-5B, cross-sectional views of structure 500 being processed according to some embodiments of the present technology are illustrated. As illustrated in FIG. 5A substrate 505 may have a plurality of stacked layers overlying the substrate, which may be silicon, silicon germanium, or other substrate materials. The layers may include IPD layers including dielectric material 510, which may be silicon-and-oxygen-containing material (e.g., silicon oxide), in alternating layers with placeholder material 520, which may be silicon-and-nitrogen-containing material (e.g., silicon nitride), silicon-carbon-and-nitrogen-containing material, silicon-oxygen-and-nitrogen-containing material, or silicon-carbon-oxygen-and-nitrogen-containing material. Although illustrated with only seven layers of material, exemplary structures may include any number of layers, and it is to be understood that the figures are only schematics to illustrate aspects of the present technology. Feature 530, which may be a memory hole or trench, may be defined through the stacked structure to the level of substrate 505. Feature 530 may be defined by sidewalls 532 that may be composed of the alternating layers of dielectric material 510 and placeholder material 520.

In FIG. 5B is illustrated a structure after methods according to the present technology have begun to be performed, such as discussed with respect to FIG. 4 above. Precursors or, if formed, remote plasma effluents may be delivered to the substrate processing region, where the precursors and/or remote plasma effluents may interact with the substrate and exposed materials. As described above, at least a portion of silicon-and-oxygen-containing material, such as dielectric material 510, may be selectively etched and recessed relative to placeholder material 520. By utilizing precursors and processing as discussed throughout the present technology, silicon-and-oxygen-containing material may be isotropically or laterally etched from between sections of silicon-and-nitrogen-containing material with a uniform amount of etching along a length or depth of the features such that top-to-bottom loading may be controlled.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a first fluorine-containing precursor and a nitrogen-containing precursor to a processing region of a semiconductor processing chamber, wherein a substrate is disposed within the processing region, and wherein one or more features extend through alternating layers of a silicon-and-oxygen-containing material and a silicon-and-nitrogen-containing material are disposed on the substrate;
providing a second fluorine-containing precursor to the processing region of the semiconductor processing chamber; and
contacting the substrate with the first fluorine-containing precursor, the nitrogen-containing precursor, and the second fluorine-containing precursor, wherein the contacting etches a portion of the silicon-and-oxygen-containing material, and wherein a top-to-bottom loading is characterized by less than 1.2.

2. The semiconductor processing method of claim 1, wherein the first fluorine-containing precursor comprises hydrogen fluoride (HF).

3. The semiconductor processing method of claim 1, wherein the nitrogen-containing precursor comprises ammonia (NH₃).

4. The semiconductor processing method of claim 1, wherein the silicon-and-nitrogen-containing material further comprises oxygen and/or carbon.

5. The semiconductor processing method of claim 1, wherein a flow rate ratio of the first fluorine-containing precursor relative to the nitrogen-containing precursor is between about 0.5:1 and about 2:1.

6. The semiconductor processing method of claim 1, wherein the second fluorine-containing precursor comprises silicon tetrafluoride (SiF₄).

7. The semiconductor processing method of claim 1, wherein a flow rate ratio of the second fluorine-containing precursor relative to the nitrogen-containing precursor is greater than or about 0.5:1.

8. The semiconductor processing method of claim 1, further comprising:
forming remote plasma effluents of the first fluorine-containing precursor and the nitrogen-containing precursor.

9. The semiconductor processing method of claim 1, wherein the first fluorine-containing precursor, the nitrogen-containing precursor, and the second fluorine-containing precursor form ammonium fluorosilicate ((NH₄)₂SiF₆).

10. The semiconductor processing method of claim 1, wherein a top-to-bottom loading is characterized by less than 1.

11. The semiconductor processing method of claim 1, wherein an etch rate of the silicon-and-oxygen-containing material is less than or about 20 Å/second.

12. The semiconductor processing method of claim 1, wherein a temperature within the processing region is maintained at less than or about 150° C.

13. The semiconductor processing method of claim 1, wherein a pressure within the processing region is maintained at less than or about 15 Torr.

14. A semiconductor processing method comprising:
providing a fluorine-containing precursor and a nitrogen-containing precursor to a processing region of a semiconductor processing chamber, wherein a substrate is disposed within the processing region, and wherein one or more features extend through alternating layers of a silicon-and-oxygen-containing material and a silicon-and-nitrogen-containing material are disposed on the substrate;
providing a silicon-and-fluorine-containing precursor to the processing region of the semiconductor processing chamber, wherein the fluorine-containing precursor, the nitrogen-containing precursor, and the silicon-and-fluorine-containing precursor form ammonium fluorosilicate ((NH₄)₂SiF₆); and
contacting the substrate with the fluorine-containing precursor, the nitrogen-containing precursor, and the silicon-and-fluorine-containing precursor, wherein the contacting etches a portion of the silicon-and-oxygen-containing material.

15. The semiconductor processing method of claim 14, wherein the one or more features are characterized by an aspect ratio of greater than or about 2:1.

16. The semiconductor processing method of claim 14, wherein the processing region is maintained plasma-free while contacting the substrate with the fluorine-containing precursor, the nitrogen-containing precursor, and the silicon-and-fluorine-containing precursor.

17. The semiconductor processing method of claim 14, wherein a top-to-bottom loading is characterized by less than 1.2.

18. A semiconductor processing method comprising:
providing a fluorine-containing precursor and a nitrogen-containing precursor to a processing region of a semiconductor processing chamber, wherein a substrate is disposed within the processing region, and wherein a layer of a silicon-and-oxygen-containing material disposed on the substrate defines one or more features;
providing a silicon-and-fluorine-containing precursor to the processing region of the semiconductor processing chamber, wherein the fluorine-containing precursor, the nitrogen-containing precursor, and the silicon-and-fluorine-containing precursor form ammonium fluorosilicate ((NH₄)₂SiF₆); and
contacting the substrate with the fluorine-containing precursor, the nitrogen-containing precursor, and the silicon-and-fluorine-containing precursor, wherein the contacting etches a portion of the layer of the silicon-and-oxygen-containing material, and wherein a top-to-bottom loading is characterized by less than 1.1.

19. The semiconductor processing method of claim 18, wherein the one or more features are characterized by a depth of greater than or about 50 nm.

20. The semiconductor processing method of claim 18, wherein a flow rate of the silicon-and-fluorine-containing precursor is less than a flow rate of the fluorine-containing precursor and a flow rate of the nitrogen-containing precursor.
